(19) United States
(12) Patent Application Publication
(10) Pub. No.: US 2013/0340530 A1
(43) Pub. Date: Dec. 26, 2013

(54) ULTRASONIC TESTING DEVICE WITH CONICAL ARRAY

(71) Applicant: York Oberdoerfer, Langenfeld (DE)

(72) Inventor: York Oberdoerfer, Langenfeld (DE)

(73) Assignee: GENERAL ELECTRIC COMPANY, Schenectady, NY (US)

(21) Appl. No.: 13/527,762

(22) Filed: Jun. 20, 2012

(51) Int. Cl. G01N 29/00; G01R 3/00

(52) U.S. Cl. 73/632; 29/595

(57) ABSTRACT

The present application provides an ultrasonic testing device. The ultrasonic testing device may include a conical backing and an ultrasonic transducer assembly positioned on the conical backing. The ultrasonic transducer assembly may include a printed circuit substrate with a number of separate transducer elements.

### TECHNICAL FIELD

The present disclosure relates generally to ultrasonic devices used for non-destructive testing and more particularly to ultrasonic testing devices having a conical array of separate transducer elements with gaps therebetween and methods of assembly thereof.

### BACKGROUND OF THE INVENTION

Non-destructive testing such as ultrasonic testing may be used to inspect various types of materials and components. Specifically, ultrasonic testing is a suitable method for finding internal flaws and/or material characteristics such as thickness and the like in most types of sound conducting materials. Such sound conducting materials include most metals and other types of substantially rigid materials. Generally described, such flaws or characteristics may be detected based upon changes in the reflection of sound waves on a boundary surface of the component with a generally high degree of accuracy.

Ultrasonic testing of, for example, tubes or axles with bores therein may require the use of a conical array to test under a certain angle of incidence. In creating the conical array, a large number of transducer elements may be positioned about the circumference so as to ensure complete coverage in the direction of rotation. Moreover, the ability to phase requires a couple of transducer elements with a width in range of a given wavelength. To position the transducer elements, however, may be time consuming given the need for manually positioning and attaching the elements thereon. Moreover, although a substrate material may be used to contact a large number of elements in a linear array, such a substrate has not been capable of accommodating the configuration of a conical array.

There is thus a desire for an improved ultrasonic testing device using a conical array and a method of assembling the same. Preferably such a conical array can accommodate a large number of transducer elements with the use of a flexible printed circuit substrate material while avoiding the time and expense required with manual assembly.

### SUMMARY OF THE INVENTION

In one exemplary embodiment, an ultrasonic testing device is provided.

The ultrasonic testing device may include a conical backing and an ultrasonic transducer assembly positioned on the conical backing. The ultrasonic transducer assembly may include a printed circuit substrate with a number of separate transducer elements.

In a further exemplary embodiment, a method of assembling an ultrasonic testing device is provided. The method may include the steps of attaching at least one transducer to a printed circuit substrate, arranging a number of separate transducer elements on the printed circuit substrate, attaching the printed circuit substrate to a backing, and folding the separate transducer elements over the backing into a conical array.

In a further exemplary embodiment, an ultrasonic testing device is provided. The ultrasonic testing device may include a backing configured as a conical array, a printed circuit substrate positioned on the backing, and means for producing a plurality of separated ultrasound waves attached to the printed circuit substrate.

These and other features and improvements of the present disclosure will become apparent to one of ordinary skill in the art upon review of the following detailed description when taken in conjunction with the several drawings and the appended claims.

### BRIEF DESCRIPTION OF THE DRAWINGS

FIG. 1 is a schematic diagram showing an ultrasonic device configured as a conical array.

FIG. 2 is a side plan view of the ultrasonic device of FIG. 1.

FIG. 3 is a schematic diagram of an ultrasonic device configured as a conical array as may be described herein.

FIG. 4 is a schematic view of an ultrasound transducer assembly as may be used with the ultrasonic device of FIG. 3 before the separation cuts.

FIG. 5 is a schematic view of the ultrasonic transducer assembly as may be used with the ultrasonic device of FIG. 3 after the separation cuts.

FIG. 6 is a schematic plan view of the conical array of FIG. 2 with the ultrasonic transducer assembly.

FIG. 7 is a flow chart of the assembly steps herein.

### DETAILED DESCRIPTION

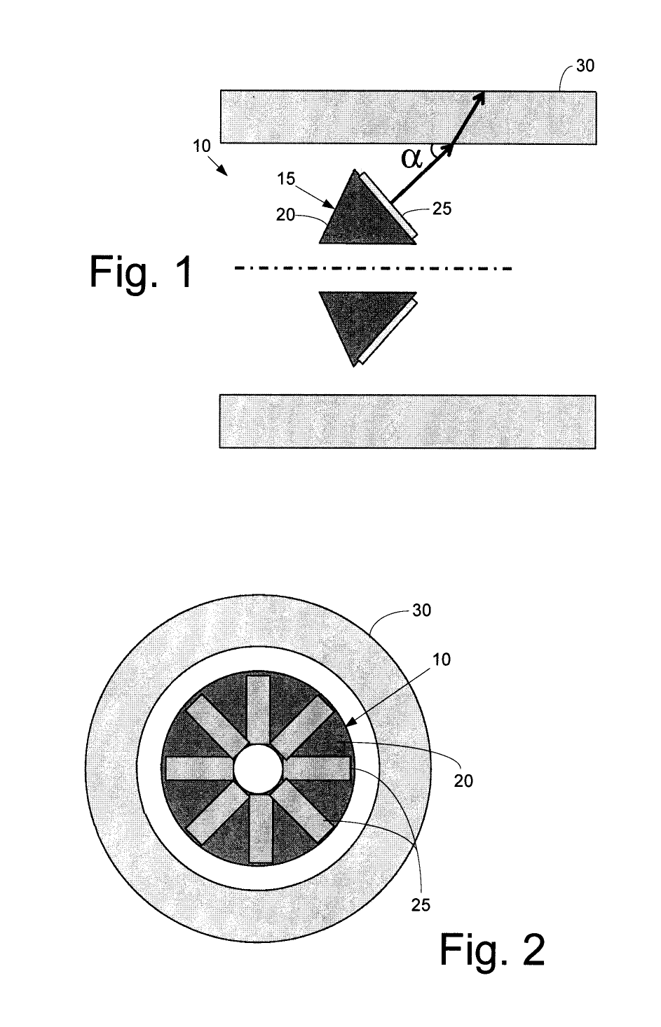

Referring now to the drawings, in which like numerals refer to like elements throughout the several views, FIGS. 1 and 2 show an ultrasonic testing device 10. The ultrasonic testing device 10 may be configured as a conical array 15. The conical array 15 includes a backing 20 with a substantially conical shape. The ultrasonic testing device 10 further includes a number of transducers 25. The transducers 25 may be positioned about the backing 20 of the conical array 15. The transducers 25 are generally positioned and glued manually to the backing 20. The use of the conical array 15 allows sound wave propagation by the transducers 25 at a desired angle of incidence. The ultrasonic testing device 10 may be inserted within a tube 30 for testing the walls thereof in a manner similar to that described above.

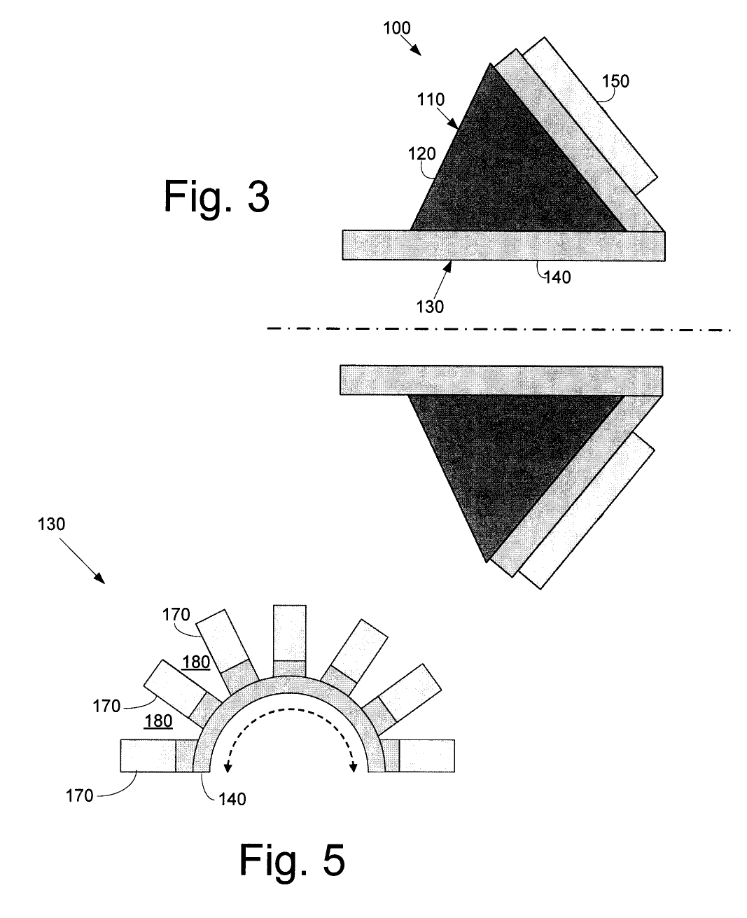

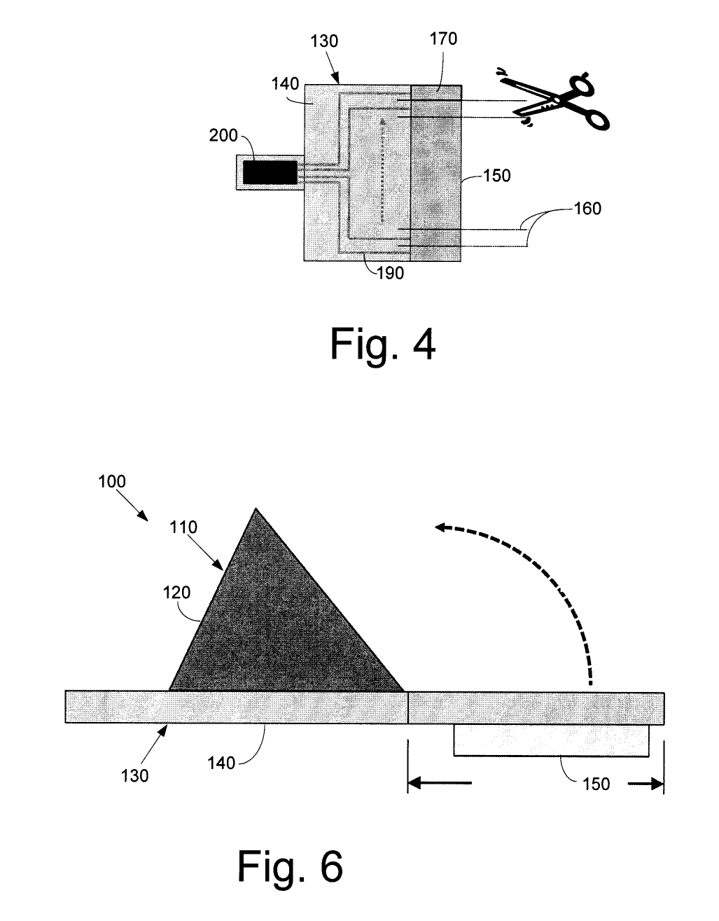

FIG. 3 shows an example of an ultrasonic testing device 100 as described herein. The ultrasonic testing device 100 may be configured as a conical array 110. The conical array 110 may include a backing 120 with a substantially conical shape. The conical backing 120 may be made out of any type of material that does not interfere with the ultrasonic waves produced herein. The ultrasonic testing device 100 and the conical backing 120 may have any size. Other components and other configurations may be used herein.

The ultrasonic testing device 100 also may include an ultrasonic transducer assembly 130. The ultrasonic transducer assembly 130 may include a printed circuit substrate 140 for positioning on the conical backing 120. The substrate 140 may be any type of thin film, flexible, printed circuit material such as, by way of example and not by limitation, a polyimide film, an electrodeposited copper foil, and the like. Non-metallic materials also may be used. A transducer 150 may be attached to the printed circuit substrate 140. The transducer 150 may be any type of piezoelectric element that converts electrical energy into sound waves. Moreover, a number of individual transducers 150 may be applied to the printed circuit substrate 140. Other components and other configurations may be used herein.

In order to accommodate the shape of the conical array 110, the transducer 150 of the ultrasonic transducer assembly 130 may have a number of separation cuts 160 performed thereon. The separation cuts 160 may be made manually or in an automated fashion including laser cutting, die cutting, and other techniques. Once the separation cuts 160 are complete, a number of separate transducer elements 170 remain with a gap 180 therebetween. The separation cuts 160 may continue beyond the transducer 150 and into the printed circuit substrate 140. The separate transducer elements 170 with the gaps 180 therebetween may be expanded as is shown in FIG. 5. Any number of the separation cuts 160 and the separate transducer elements 170 may be used herein. The separate transducer elements 170 and the gaps 180 therebetween may have any size, shape, or configuration and may vary according to the size, shape, and configuration of the conical backing 120. The separation cuts 160 also may be applied to the printed circuit substrate 140 with multiple transducers 150 thereon. Other components and other configurations may be used.

Each of the separate transducer elements 170 may be in communication with a conductor 190. The conductors 190, in turn, may be in communication with a connector/soldering terminal 200 and the like. The conductors 190 and the connector/soldering terminal may be of conventional design. As is illustrated, in FIG. 6, the printed circuit substrate 140 with the separate transducer elements 170 of the ultrasonic transducer assembly 130 then may be attached to the backing 120 of the conical array 110. The separate transducer elements 170 may be folded to the outside (or the inside) of the conical backing 120 to form the conical configuration of elements. The ultrasonic transducer assembly 130 thus may accommodate the full circumference of the conical array 110. The connector/soldering terminal 200 may be placed in communication with a control unit in a conventional fashion.

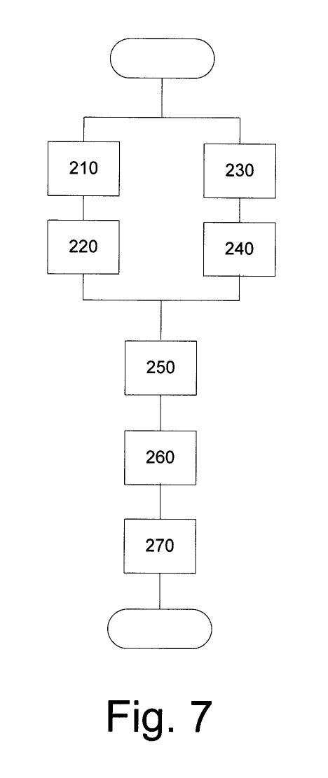

FIG. 7 shows a flow chart of the high level steps that may be used to create the ultrasonic transducer device 100. The transducer 150 may be attached to the printed circuit substrate 140 in a first step 210. The separation cuts 160 may be applied to the transducer 150 and arranged to form the separate transducer elements 170 with the gaps 180 therebetween in a second step 220. Alternatively, a number of individual transducers 150 may be attached to the printed circuit substrate 140 in an alternative first step 230. The separation cuts 160 may be applied to the printed circuit substrate 140 and arranged to form the separate transducer elements 170 with the gaps 180 therebetween in an alternative second step 240. In either example, the conductors 190 may be coupled to the separate transducer elements 170 in a third step 250. The printed circuit substrate 140 may be attached to the backing 120 in a fourth step 260. The separate transducer elements 170 may be folded over the backing 120 in a fifth step 270 to complete the ultrasonic testing device 100. These steps may be performed in differing order. Additional steps may be used herein.

The ultrasonic testing device 100 thus provides the conical array 110 with the ultrasonic transducer assembly 130 without having to individually position and glue or otherwise attach a number of the transducers 150. Rather, the separation cuts 160 produce the separate transducer elements 170 with the gaps 180 therebetween so as to accommodate the shape of the conical array 110 by folding the separate transducer elements 170 about the conical backing 120. Similarly, the separation cuts 160 into the printed circuit substrate 140 also may accommodate multiple individual transducers 150. The ultrasonic testing device 100 thus may be assembled as a phased array in less time and with less labor as compared to known ultrasonic devices typically used with conical arrays.

It should be apparent that the foregoing relates only to certain embodiments of the present invention. Numerous changes and modifications may be made herein by one of ordinary skill in the art without departing from the general spirit and scope of the invention herein as defined by the following claims and the equivalents thereof.

I claim:

1. An ultrasonic testing device, comprising:
a conical backing; and
an ultrasonic transducer assembly positioned on the conical backing;
the ultrasonic transducer assembly comprising a printed circuit substrate with a plurality of separate transducer elements.

2. The ultrasonic testing device of claim 1, wherein the ultrasonic transducer assembly is positioned as a conical array on the conical backing.

3. The ultrasonic testing device of claim 1, wherein the ultrasonic transducer assembly comprises a plurality of gaps between the plurality of separate transducer elements.

4. The ultrasonic testing device of claim 3, wherein the plurality of gaps extend within the printed circuit substrate.

5. The ultrasonic testing device of claim 1, wherein the printed circuit substrate comprises a metallic foil.

6. The ultrasonic testing device of claim 5, wherein the metallic foil comprises an electrodeposited copper foil.

7. The ultrasonic testing device of claim 1, wherein the ultrasonic transducer assembly comprises a plurality of conductors in communication with the plurality of separate transducer elements.

8. The ultrasonic testing device of claim 1, wherein the conical backing is configured for a predetermined angle of incidence.

9. The ultrasonic testing device of claim 1, wherein the ultrasonic transducer assembly comprises a phased array of the plurality of separate transducer elements.

10. The ultrasonic testing device of claim 1, wherein the plurality of separate transducer elements are not fixedly attached to the conical backing.

11. A method of assembling an ultrasonic testing device, comprising:
attaching at least one transducer to a printed circuit substrate;
arranging a plurality of separate transducer elements on the printed circuit substrate;
attaching the printed circuit substrate to a backing; and
folding the plurality of separate transducer elements over the backing into a conical array.

12. The method of claim 11, wherein the step of arranging a plurality of separate transducer elements comprises cutting the at least one transducer.

13. The method of claim 11, wherein the step of arranging a plurality of separate transducer elements comprises cutting the at least one transducer and the printed circuit substrate.

14. The method of claim 11, wherein the step of arranging a plurality of separate transducer elements comprises attaching a plurality of transducers to the printed circuit substrate.

15. The method of claim 14, wherein the step of arranging a plurality of separate transducer elements comprises cutting the printed circuit substrate.

16. The method of claim 11, wherein the step of arranging a plurality of separate transducer elements comprises forming a plurality of gaps between the plurality of separate transducer elements.

17. The method of claim 11, wherein the step of attaching the printed circuit substrate to a backing comprises attaching the printed circuit substrate to a conical backing.

18. The method of assembly of claim 11, further comprising coupling a connector to each of the separate transducer elements.

19. The method of assembly of claim 11, further comprising coupling each of the connectors to a terminal.

20. An ultrasonic testing device, comprising:
a backing configured as a conical array;
a printed circuit substrate positioned on the backing; and
means for producing a plurality of separated ultrasound waves attached to the printed circuit substrate.
